(19) United States
(12) Patent Application Publication
(10) Pub. No.: US 2024/0339674 A1
(43) Pub. Date: Oct. 10, 2024

(54) POWER SOURCE SYSTEM

(71) Applicant: TOYOTA JIDOSHA KABUSHIKI KAISHA, Toyota-shi (JP)

(72) Inventors: Yasuhiro ENDO, Toyota-shi (JP); Junta IZUMI, Nagoya-shi (JP); Hironori MIKI, Nagoya-shi (JP); Kenji KIMURA, Nagoya-shi (JP); Takayuki BAN, Nishio-shi (JP); Takuya MIZUNO, Nagakute-shi (JP); Naoki YANAGIZAWA, Nagakute-shi (JP); Shuji TOMURA, Nagakute-shi (JP); Kazuo OOTSUKA, Nagakute-shi (JP); Hiroshi TSUKADA, Nagakute-shi (JP)

(73) Assignee: TOYOTA JIDOSHA KABUSHIKI KAISHA, Toyota-shi (JP)

(21) Appl. No.: 18/427,018

(22) Filed: Jan. 30, 2024

(30) Foreign Application Priority Data
Apr. 5, 2023 (JP) 2023-061417

(51) Int. Cl. H01M 10/42; G01R 19/10; G01R 19/165; H01M 10/48; H01M 50/509; H02J 7/00

(52) U.S. Cl. CPC H01M 10/4228; G01R 19/10; G01R 19/16576; H01M 10/4264; H01M 10/482; H01M 50/509; H02J 7/0013; H02J 7/0047; H02J 7/0063

(57) ABSTRACT

A battery string is configured such that a plurality of battery circuit modules can be connected in series. A middle point between a first capacitor and a second capacitor provided on a detection line connecting a positive electrode output line and a negative electrode output line of the battery string to each other is grounded by a ground line through a limiting resistor. During operation of the battery string, an electric leakage detection unit sets a battery circuit module in a pass-through state, and detects electric leakage in the battery string based on a differential voltage that is a difference between a first voltage being the voltage of the first capacitor and a second voltage being the voltage of the second capacitor.

### CROSS-REFERENCE TO RELATED APPLICATION

This application claims priority to Japanese Patent Application No. 2023-061417 filed on Apr. 5, 2023, incorporated herein by reference in its entirety.

### BACKGROUND

### 1. Technical Field

This disclosure relates to a power source system.

### 2. Description of Related Art

Japanese Unexamined Patent Application Publication No. 2018-174607 (JP 2018-174607 A) discloses a power source system (power source device) including a battery string in which a plurality of battery circuit modules (battery modules) can be connected in series. Each battery circuit module included in the battery string includes a battery, a first switch connected in parallel to the battery, a second switch connected in series to the battery, and a first output terminal and a second output terminal to which the voltage of the battery is applied when the first switch is in an OFF state while the second switch is in an ON state. The ON/OFF states of the first switch and the second switch are controlled by a gate driving signal, and the gate driving signal is transmitted to a battery circuit module in a next stage connected in series with a predetermined delay time. As the first switches and the second switches of the respective battery circuit modules included in the battery string are controlled by the gate driving signal, the output voltage of the battery string can be adjusted to a desired magnitude.

### SUMMARY

It is desirable to detect electric leakage in a battery string. In JP 2018-174607 A, no mention is made of detecting electric leakage in the battery string.

An object of this disclosure is to detect electric leakage in a battery string.

(1) A power source system of this disclosure includes a battery string in which a plurality of battery circuit modules is connected in series. Each battery circuit module includes a battery, a first switch connected in parallel to the battery, a second switch connected in series to the battery, and a first output terminal and a second output terminal to which a voltage of the battery is applied when the first switch is in an OFF state while the second switch is in an ON state. The power source system further includes a control device, a first capacitor and a second capacitor, a ground line, a first voltage sensor, a second voltage sensor, and an electric leakage detection unit. The control device controls an output voltage of the battery string by controlling ON/OFF states of the first switch and the second switch. The first capacitor and the second capacitor are connected in series to a detection line connecting a positive electrode output line and a negative electrode output line of the battery string to each other. The ground line grounds the detection line between the first capacitor and the second capacitor through a limiting resistor. The first voltage sensor acquires a first voltage that is the voltage of the first capacitor. The second voltage sensor acquires a second voltage that is the voltage of the second capacitor. The electric leakage detection unit detects electric leakage in the battery string. The electric leakage detection unit is configured to execute a first electric leakage detection process and a second electric leakage detection process during operation of the battery string. The first electric leakage detection process includes a process of determining that electric leakage exists in the battery string when a differential voltage that is a difference between the first voltage and the second voltage is equal to or higher than a predetermined value. The second electric leakage detection process includes a process of setting at least one battery circuit module among the plurality of battery circuit modules in a pass-through state in which the first switch is in a normally ON state while the second switch is in a normally OFF state, and determining that electric leakage exists in the battery string when the differential voltage is equal to or higher than the predetermined value.

According to this configuration, the control device controls the ON/OFF states of the first switches and the second switches of the battery circuit modules. Thus, the number of battery circuit modules to be connected is controlled and thereby the output voltage of the battery string is controlled. On the detection line connecting the positive electrode output line and the negative electrode output line of the battery string to each other, the first capacitor and the second capacitor connected in series are provided, and the detection line between the first capacitor and the second capacitor is grounded by the ground line through the limiting resistor. The first voltage sensor acquires the first voltage that is the voltage of the first capacitor, and the second voltage sensor acquires the second voltage that is the voltage of the second capacitor. The electric leakage detection unit executes the first electric leakage detection process of, during operation of the battery string, determining that electric leakage exists in the battery string when the differential voltage that is the difference between the first voltage and the second voltage is equal to or higher than the predetermined value. The electric leakage detection unit executes the second electric leakage detection process of, during operation of the battery string, setting at least one battery circuit module in the pass-through state in which the first switch is in the normally ON state while the second switch is in the normally OFF state, and determining that electric leakage exists in the battery string when the differential voltage is equal to or higher than the predetermined value.

A point (middle point) between the first capacitor and the second capacitor connected in series is grounded through the limiting resistor. Therefore, when no electric leakage exists in the battery string, the first voltage (the voltage of the first capacitor) and the second voltage (the voltage of the second capacitor) are equal during operation of the battery string. When electric leakage occurs in the battery string, the first voltage and the second voltage come out of balance (equilibrium). Thus, when the differential voltage (the difference between the first voltage and the second voltage) is equal to or higher than the predetermined value, it can be determined that electric leakage exists in the battery string.

When the site of electric leakage is near the center of the plurality of battery circuit modules connected in series, the number of battery circuit modules operating on an upstream side of the site of electric leakage (the side of the positive electrode output line of the battery string) and the number of battery circuit modules operating on a downstream side of the site of electric leakage (the side of the negative electrode output line of the battery string) can be the same number. In this case, even when electric leakage occurs in the battery string, the first voltage and the second voltage come into balance (equilibrium) and the differential voltage is lower than the predetermined value during operation of the battery string. In the second electric leakage detection process, during operation of the battery string, the electric leakage detection unit sets at least one battery circuit module in the pass-through state (in which the first switch is in the normally ON state while the second switch is in the normally OFF state), and determines that electric leakage exists in the battery string when the differential voltage is equal to or higher than the predetermined value. Since at least one battery circuit module is put in the pass-through state in the second electric leakage detection process, even when the site of electric leakage is near the center of the plurality of battery circuit modules connected in series, a difference occurs between the number of battery circuit modules operating upstream of the site of electric leakage and the number of those operating downstream thereof, so that the electric leakage can be detected using the differential voltage.

(2) The electric leakage detection unit may execute the second electric leakage detection process when the electric leakage detection unit has determined in the first electric leakage detection process that no electric leakage exists in the battery string.

The likelihood that electric leakage occurs in a battery circuit module at a site other than near the center of the plurality of battery circuit modules connected in series is higher than the likelihood that electric leakage occurs near that center. According to this configuration, electric leakage in the battery string can be detected more efficiently.

(3) The power source system may include a plurality of battery strings that is connected in parallel, and each of the plurality of battery strings may be formed by the above-described battery string. The detection line may connect to each other a positive electrode line to which a positive electrode output line of each battery string is connected and a negative electrode line to which a negative electrode output line of each battery string is connected.

According to this configuration, electric leakage in the plurality of battery strings connected in parallel can be detected by the electric leakage detection unit.

According to this disclosure, electric leakage in a battery string can be detected.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a view showing the schematic configuration of a power source system according to an embodiment of this disclosure;

FIG. 2 is a view showing the configuration of a battery string St;

FIG. 3A is a view illustrating the operation of a battery circuit module M controlled by a gate signal;

FIG. 3B is a view illustrating the operation of the battery circuit module M controlled by the gate signal;

FIG. 3C is a view illustrating the operation of the battery circuit module M controlled by the gate signal;

FIG. 3D is a view illustrating the operation of the battery circuit module M controlled by the gate signal;

FIG. 4 is a view illustrating a relationship between a first voltage and a second voltage when electric leakage occurs in a battery string;

FIG. 5 is a flowchart showing one example of an electric leakage detection process executed in an electric leakage detection unit; and

FIG. 6 is a view showing the schematic configuration of a power source system in a modified example.

### DETAILED DESCRIPTION OF EMBODIMENTS

An embodiment of this disclosure will be described in detail with reference to the drawings. The same or corresponding parts in the drawings will be denoted by the same reference sign and description thereof will not be repeated.

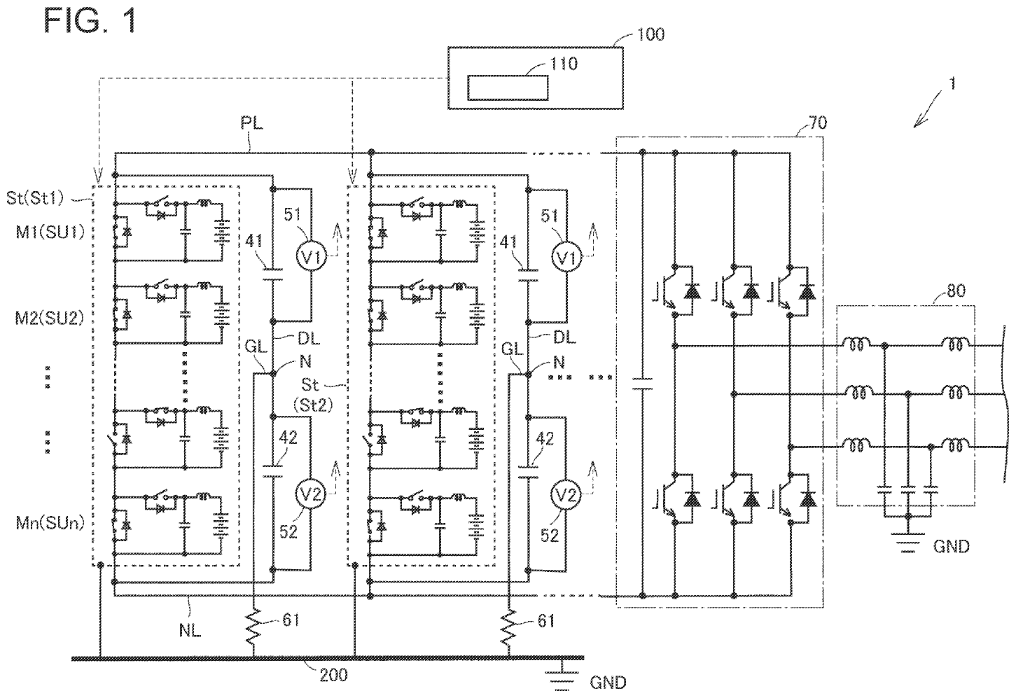

FIG. 1 is a view showing the schematic configuration of a power source system according to an embodiment of this disclosure. Referring to FIG. 1, a power source system 1 includes a plurality of battery strings St, an inverter 70, an LCL filter 80, and a control device 100. The control device 100 may be a computer and includes, for example, a processor, a storage device, and a communication interface (I/F). In the storage device, for example, programs to be executed by the processor and information (e.g., maps, mathematical expressions, and various parameters) to be used in the programs are stored.

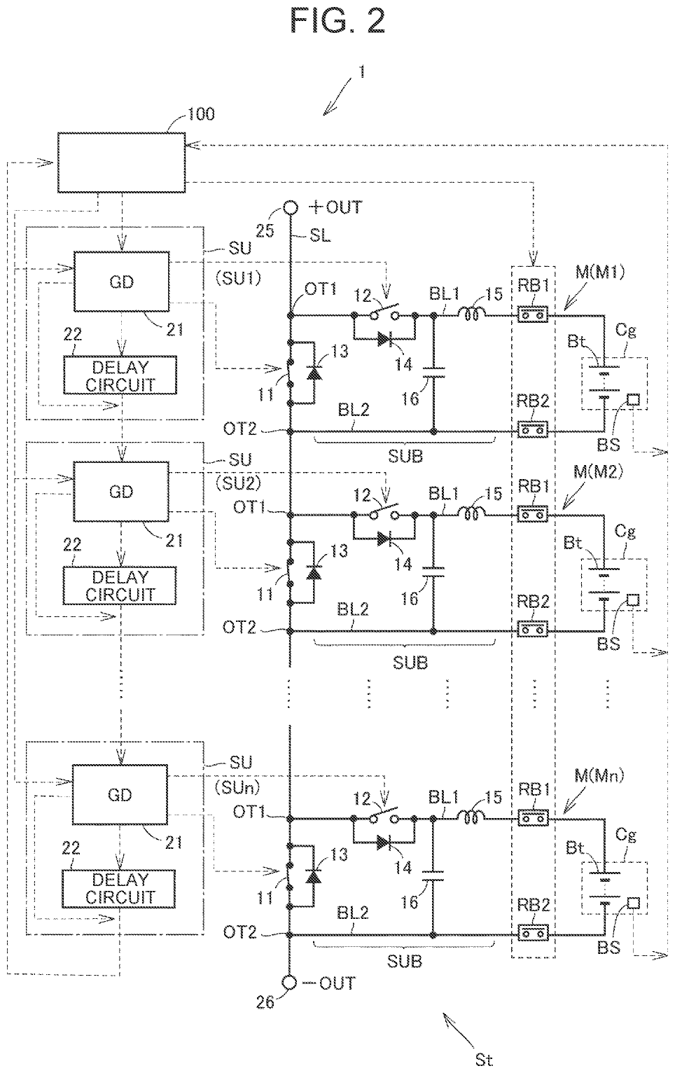

FIG. 2 is a view showing the configuration of a battery string St. The battery string St includes a plurality of battery circuit modules M (M1 to Mn; n is a positive integer). The number of battery circuit modules M included in the battery string St is arbitrary, and may be 5 to 20 or may be 100 or more. In this embodiment, each battery string St includes the same number of battery circuit modules M, but the number of battery circuit modules M may differ among the battery strings St.

Each battery circuit module M includes an electric power circuit SUB and a cartridge Cg. The cartridge Cg includes a battery Bt and a monitoring unit BS. As the electric power circuit SUB and the battery Bt are connected to each other, the battery circuit module M including the battery Bt is formed. Drive circuits SU (SU1 to SUn) are configured to drive switching elements (an SW 11 and an SW 12 to be described later) included in the battery circuit module M. The battery Bt may be a nickel-metal hydride secondary battery or a lithium-ion secondary battery, and the battery Bt may be manufactured by connecting secondary batteries having been used in an electrified vehicle in series.

As shown in FIG. 2, the electric power circuit SUB and the cartridge Cg are connected to each other through breakers RB1, RB2 (which will be referred to as “breakers RB” when no distinction is made therebetween). The breakers RB switch a connection state (continuous/interrupted) between the electric power circuit SUB and the cartridge Cg in accordance with a command from the control device 100. The breakers RB may be configured such that a user can manually turn them on and off, and this configuration allows the cartridge Cg to be attached to and detached from the electric power circuit SUB.

In the cartridge Cg, the monitoring unit BS is configured to detect a state (e.g., a voltage, a current, and a temperature) of the battery Bt and output a detection result to the control device 100.

The battery circuit modules M included in the battery string St are connected to one another by a common electric wire SL. The electric wire SL includes output terminals OT1, OT2 of each battery circuit module M. The output terminal OT2 of each battery circuit module M is connected to the output terminal OT1 of another battery circuit module M adjacent to that battery circuit module M, so that the battery circuit modules M included in the battery string St are connected to one another.

The battery circuit module M (electric power circuit SUB) includes a first switching element 11 (hereinafter referred to as “SW 11”), a second switching element 12 (hereinafter referred to as “SW 12”), a first diode 13, a second diode 14, a choke coil 15, a capacitor 16, and the output terminals OT1 and OT2. Each of the SW 11 and the SW 12 is driven by the drive circuit SU. The SW 11 and the SW 12 according to this embodiment correspond to examples of “first switch” and “second switch,” respectively, according to this disclosure.

Between the output terminals OT1 and OT2 of the battery circuit module M, the SW 11, the capacitor 16, and the battery Bt are connected in parallel. The SW 11 is located on the electric wire SL and configured to switch the connection state (continuous/interrupted) between the output terminal OT1 and the output terminal OT2. The output terminal OT1 is connected to a positive electrode of the battery Bt through an electric wire BL1, and the output terminal OT2 is connected to a negative electrode of the battery Bt through an electric wire BL2. On the electric wire BL1, the SW 12 and the choke coil 15 are further provided. In the battery circuit module M, the voltage of the battery Bt is applied to between the output terminals OT1 and OT2 when the SW12 connected in series to the battery Bt is in an ON state (connected state) while the SW11 connected in parallel to the battery Bt is in an OFF state (shut-off state).

Between the output terminals OT1, OT2 and the battery Bt, the capacitor 16 connected to each of the electric wire BL1 and the electric wire BL2 is provided. Each of the SW 11 and the SW 12 is, for example, a field-effect transistor (FET). The first diode 13 and the second diode 14 are connected in parallel to the SW 11 and the SW 12, respectively. Each of the SW 11 and the SW 12 may be a switching element other than an FET.

The control device 100 generates a gate signal. The drive circuits SU (SU1 to SUn) are provided for the respective battery circuit modules M (M1 to Mn), and each include a gate driver (GD) 21 that drives the SW 11 and the SW 12 in accordance with the gate signal and a delay circuit 22 that delays the gate signal. Turning on and off of each of the SW 11 and the SW 12 included in the battery circuit module M is controlled in accordance with the gate signal.

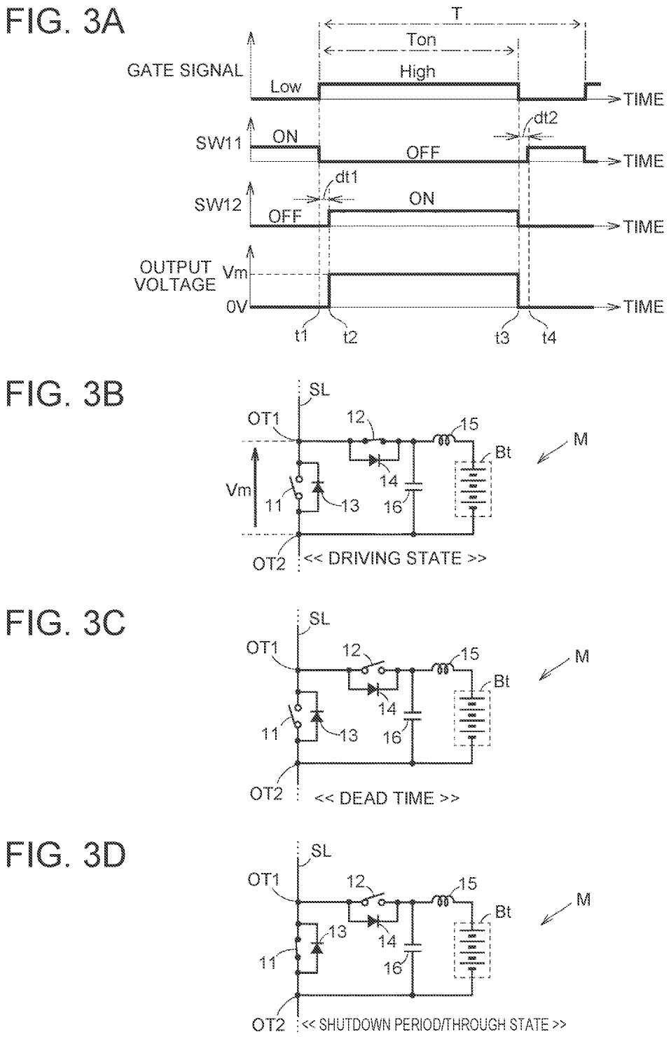

FIG. 3A to FIG. 3D are views illustrating the operation of the battery circuit module M controlled by the gate signal. FIG. 3A is a time chart showing one example of the operation of the battery circuit module M, and in this embodiment, a rectangular wave signal is adopted as the gate signal for driving the SW 11 and the SW 12. “Low” and “High” of the gate signal shown in FIG. 3A represent an L-level and an H-level, respectively, of the gate signal (rectangular wave signal). “Output voltage” is a voltage output to between the output terminals OT1 and OT2. In an initial state of the battery circuit module M, the gate signal is not input into the drive circuit SU (gate signal: L-level) and the SW 11 and the SW 12 are in the ON state and the OFF state, respectively. The states (ON/OFF) of the SW 11 and the SW 12 switch according to rise and fall of the gate signal. The control device 100 performs PWM control using the gate signal.

When the gate signal is input into the drive circuit SU, the GD 21 drives the SW 11 and the SW 12 in accordance with the input gate signal. In the example shown in FIG. 3A to FIG. 3D, the gate signal rises from the L-level to the H-level at timing t1, and the SW 11 switches from the ON state to the OFF state at the same time as the rise of the gate signal. At timing t2 after a delay of a predetermined time (dead time dt1) from the rise of the gate signal, the SW 12 switches from the OFF state to the ON state. As a result, the battery circuit module M assumes a driving state (connected state), and as the SW 11 assumes the OFF state and the SW 12 assumes the ON state as shown in FIG. 3B, the voltage of the battery Bt is applied to between the output terminals OT1 and OT2. In this disclosure, a state where “the SW 11 is in the OFF state while the SW 12 is in the ON state” and where the battery circuit module M is in the connected state will be referred to as “driving state.”

Referring to FIG. 3A, when the gate signal falls from the H-level to the L-level at timing t3, the SW 12 switches from the ON state to the OFF state at the same time as the fall of the gate signal. As a result, the battery circuit module M assumes a through state. In the battery circuit module M in the through state, as the SW 12 is in the OFF state, the voltage of the battery Bt is not applied to between the output terminals OT1 and OT2. Thereafter, at timing t4 after a delay of a predetermined time (dead time dt2) from the fall of the gate signal, the SW 11 switches from the OFF state to the ON state. The dead time dt1 and the dead time dt2 may be the same with or different from each other.

During the dead times dt1, dt2, both the SW 11 and the SW 12 are in the OFF state as shown in FIG. 3C. This helps prevent the SW 11 and the SW 12 from assuming the ON state at the same time (the battery circuit module M from assuming a short-circuit state).

When a period from the end of the dead time dt2 (t4) until the battery circuit module M assumes the driving state is referred to as “shutdown period,” during the shutdown period, as shown in FIG. 3D, the SW 11 is in the ON state and the SW 12 is in the OFF state as in the initial state. In this disclosure, a state where “the SW 11 is in the ON state while the SW 12 is in the OFF state” and where the battery circuit module M is in a non-driving state will be referred to as “through state.”

The gate signal is transmitted from an upstream drive circuit SU to a downstream drive circuit SU while being delayed each time by a predetermined delay time Td by the delay circuit 22. When the control device 100 receives the gate signal from the delay circuit 22 of a most downstream drive circuit SU (SUn), the control device 100 outputs a new gate signal to a most upstream drive circuit SU (SU0). A period T of the gate signal is a total of the delay times Td of the delay circuits 22 included in the battery string St, and when the number of all battery circuit modules M (the total number of battery circuit modules M) included in the battery string St is represented by No, the period Tis set as “T=Td×No.” By controlling the duty ratio (the time of the H-level:an ON time Ton) of the gate signal, the number of battery circuit modules M in the driving state (the number of battery circuit modules M that assume the driving state at the same time) can be adjusted.

By controlling the battery circuit modules M included in the battery string St as described above, the number of battery circuit modules M in the driving state (the number of battery circuit modules M that assume the driving state at the same time) can be adjusted. The voltage (output voltage) between a positive electrode terminal 25 and a negative electrode terminal 26 of the battery string St can be thereby controlled. Thus, the battery string St can output a voltage from 0 [V] to a total of the voltages of the respective batteries Bt (cartridges Cg) included in the battery string St. The positive electrode terminal 25 corresponds to one example of “positive electrode output line” of this disclosure, and the negative electrode terminal 26 corresponds to one example of “negative electrode output line” of this disclosure.

Referring to FIG. 1, in this embodiment, a plurality of battery strings St is connected in parallel. While two battery strings St (St1, St2) are shown in FIG. 1, the number of battery strings St is arbitrary. The positive electrode terminal 25 of the battery string St is connected to the positive electrode line PL and the negative electrode terminal 26 thereof is connected to the negative electrode line NL. As for reference sign “n” of the battery circuit module Mn and the drive circuit SUn, those located farthest on the side of the positive electrode line PL (upstream side) are denoted by “1” (the battery circuit module M1, the drive circuit SU1), and those located farthest on the side of the negative electrode line NL (downstream side) are denoted by “n” (the battery circuit module Mn, the drive circuit SUn). The positive electrode line PL and the negative electrode line NL are connected to the inverter 70, and three-phase alternating-current power output from the inverter 70 is supplied to a transformer or the like (not shown) through the LCL filter 80.

In a detection line DL connected to the positive electrode and the negative electrode of the battery string St (St1), a first capacitor 41 and a second capacitor 42 connected in series are provided. The capacities of the first capacitor and the second capacitor are the same. The detection line DL between the first capacitor 41 and the second capacitor 42 is connected at its middle point N to a ground line GL. The ground line GL is grounded by being connected to a metal shelf 200 or the like of the power source system 1 through a limiting resistor 61. A housing of the battery string St is also grounded on the metal shelf 200 according to class-C grounding.

A first voltage sensor 51 detects a first voltage V1 that is the voltage of the first capacitor 41 and outputs a detection signal to the control device 100. A second voltage sensor 52 detects a second voltage V2 that is the voltage of the second capacitor 42 and outputs a detection signal to the control device 100.

In this embodiment, the detection line DL, the first capacitor 41, the second capacitor 42, etc. are included for each of the plurality of battery strings St, and detection signals of the first voltage sensor 51 and the second voltage sensor 52 of each battery string St are output to the control device 100.

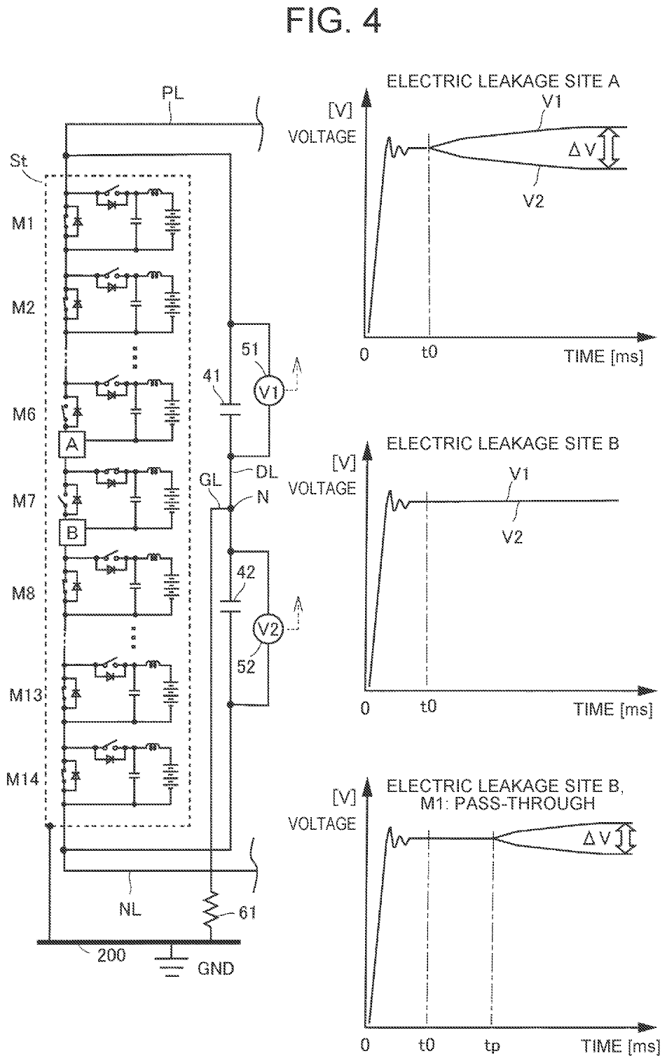

FIG. 4 is a view illustrating a relationship between the first voltage V1 and the second voltage V2 when electric leakage occurs in the battery string St. In FIG. 4, a case where the number of battery circuit modules M is 14 is shown as an example. If no electric leakage exists in the battery string St (battery circuit modules M) when the battery string St is operating with the battery modules M (drive circuits SU) controlled by the gate signal of the control device 100, the first voltage V1 and the second voltage V2 are equal.

In FIG. 4, for example, when electric leakage occurs at a site A (electric leakage site A) between a battery circuit module M6 and a battery circuit module M7, during operation of the battery string St, the number of battery circuit modules M operating on the upstream side from the electric leakage site A becomes six, and the number of battery circuit modules M operating on the downstream side from the electric leakage site A becomes eight. Thus, as in the graph shown at the top of FIG. 4, when electric leakage occurs at the electric leakage site A at time t0, a differential voltage ΔV occurs between the first voltage V1 and the second voltage V2. (In this case, the differential voltage ΔV corresponds to the voltage of one battery circuit module M (cartridge Cg).) Therefore, the electric leakage in the battery string St can be detected by obtaining the differential voltage ΔV during operation of the battery string St.

In FIG. 4, for example, when electric leakage occurs at a site B (electric leakage site B) between the battery circuit module M7 and a battery circuit module M8, during operation of the battery string St, the number of battery circuit modules M operating on the upstream side from the electric leakage site B is seven, and the number of battery circuit modules M operating on the downstream side from the electric leakage site B is seven. Thus, as in the graph shown at the center of FIG. 4, even when electric leakage occurs at the electric leakage site B at time to, the first voltage V1 and the second voltage V2 come into balance (equilibrium) and the first voltage V1 and the second voltage V2 become almost equal. Therefore, the electric leakage in the battery string St cannot be detected by obtaining the differential voltage ΔV during operation of the battery string St.

When the GD 21 allows the input gate signal to pass in a predetermined battery circuit module M (drive circuit SU) while the battery string St is operating, driving of switching of this battery circuit module M is not performed and the gate signal is transmitted to a downstream drive circuit SU. In this case, the SW 11 and the SW 12 of this battery circuit module M assume the initial state, where “the SW 11 is in the normally ON state while the SW 12 is in the normally OFF state.” In this disclosure, a state where “the SW 11 is in the normally ON state while the SW 12 is in the normally OFF state” is also referred to as “pass-through state.”

In FIG. 4, in the case where electric leakage exists at the site B (electric leakage site B) between the battery circuit module M7 and the battery circuit module M8, for example, when the battery circuit module M1 is put in the pass-through state during operation of the battery string St, the number of battery circuit modules M operating on the upstream side from the electric leakage site B is six, and the number of battery circuit modules M operating on the downstream side from the electric leakage site B is seven. Thus, as in the graph shown at the bottom of FIG. 4, when electric leakage occurs at the electric leakage site B at time t0 and the battery circuit module M1 is put in the pass-through state at time tp, a differential voltage ΔV occurs between the first voltage V1 and the second voltage V2. Therefore, even when electric leakage occurs near the center of the battery string St, the electric leakage in the battery string St can be detected by putting at least one battery circuit module M in the pass-through state and obtaining the differential voltage ΔV during operation of the battery string St.

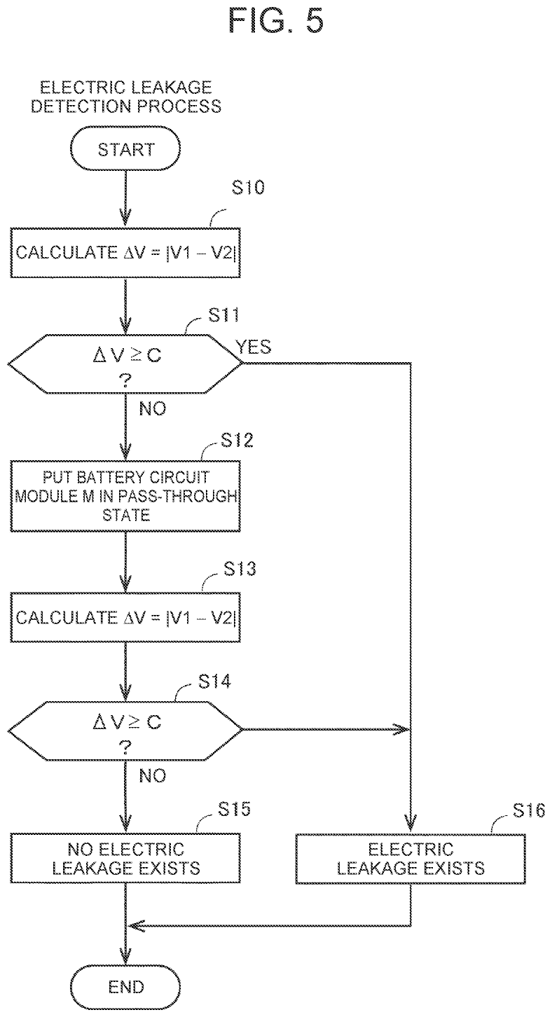

In this embodiment, an electric leakage detection unit 110 is formed, for example, as a functional block in the control device 100. FIG. 5 is a flowchart showing one example of an electric leakage detection process executed in the electric leakage detection unit 110. This flowchart may be executed in an electric leakage diagnosis mode that is executed once every predetermined period during operation of the battery string St (during operation of the power source system 1). The electric leakage diagnosis mode may be executed when electric leakage is detected by an electric leakage detector (not shown) of the power source system 1 or immediately after start-up of the power source system 1. The electric leakage detection process is executed for each battery string St.

Referring to FIG. 5, in step (hereinafter “step” will be abbreviated as “S”) 10, in the battery string St in operation, the differential voltage ΔV (=|V1−V2|) that is the difference between the first voltage V1 detected by the first voltage sensor 51 and the second voltage V2 detected by the second voltage sensor 52 is calculated.

In the subsequent S11, it is determined whether the differential voltage ΔV is equal to or higher than a predetermined value C. The predetermined value Cis a value that is set beforehand based on experiments etc. according to the voltage of the battery circuit module M (cartridge Cg), and may be, for example, one-tenth to one-third of the voltage of the battery circuit module M. When the differential voltage ΔV is lower than the predetermined value C (ΔV<C), it is determined in the negative and the process moves to S12. When the differential voltage ΔV is equal to or higher than the predetermined value C (ΔV≥C), it is determined in the affirmative and the process moves to S16.

In S12, a predetermined battery circuit module M is put in the pass-through state. In this embodiment, after the battery circuit module M1 is put in the pass-through state, the process moves to S13. In S13, in the battery string St in operation (with the battery circuit module M1 in the pass-through state), the differential voltage ΔV (=|V1−V2|) is calculated from detection signals of the first voltage sensor 51 and the second voltage sensor 52.

In the subsequent S14, it is determined whether the differential voltage ΔV calculated in S13 is equal to or higher than the predetermined value C. When the differential voltage ΔV is lower than the predetermined value C (ΔV<C), it is determined in the negative and the process moves to S15. When the differential voltage ΔV is equal to or higher than the predetermined value C (ΔV≥C), it is determined in the affirmative and the process moves to S16.

In S15, it is determined that no electric leakage exists in the battery string St, and the current routine is ended. In S16, it is determined that electric leakage exists in the battery string St, and the current routine is ended. When it is determined that electric leakage exists in the battery string St, a warning light (not shown) may be turned on to notify of the electric leakage or the operation of the power source system 1 may be stopped.

According to this embodiment, the first capacitor 41 and the second capacitor 42 connected in series are provided on the detection line DL connecting the positive electrode output line and the negative electrode output line of the battery string St to each other, and the middle point N between the first capacitor 41 and the second capacitor 42 is grounded by the ground line GL through the limiting resistor 61. The electric leakage detection unit 110 executes the first electric leakage detection process (S10, S11, S16) of, during operation of the battery string St, determining that electric leakage exists in the battery string St when the differential voltage ΔV that is the difference between the first voltage V1 being the voltage of the first capacitor 41 and the second voltage V2 being the voltage of the second capacitor 42 is equal to or higher than the predetermined value C. Thus, if electric leakage occurs in the battery string St, this electric leakage can be detected when the first voltage V1 and the second voltage V2 come out of balance (equilibrium) and the differential voltage ΔV becomes equal to or higher than the predetermined value C.

Further, the electric leakage detection unit 110 executes the second electric leakage detection process (S12, S13, S14, S16) of, during operation of the battery string St, setting the battery circuit module M1 in the pass-through state, and determining that electric leakage exists in the battery string St when the differential voltage ΔV is equal to or higher than the predetermined value C. Thus, even when the electric leakage site in the battery string St is near the center of the plurality of battery circuit modules M, a difference occurs between the number of battery circuit modules M operating upstream of the electric leakage site and those operating downstream thereof as a battery circuit module is put in the pass-through state, so that the electric leakage can be detected using the differential voltage ΔV.

In the above-described embodiment, in S12, the battery circuit module M1 is put in the pass-through state, but any one of the battery circuit modules M may be put in the pass-through state. A plurality of battery circuit modules M located on the upstream side from the center of the battery string St may be put in the pass-through state, or a plurality of battery circuit modules M located on the downstream side from the center of the battery string St may be put in the pass-through state.

In the above-described embodiment, the electric leakage detection unit 110 is formed as a functional block in the control device 100. However, a controller separate from the control device 100 may be provided, and an electric leakage detection unit may be formed in this controller.

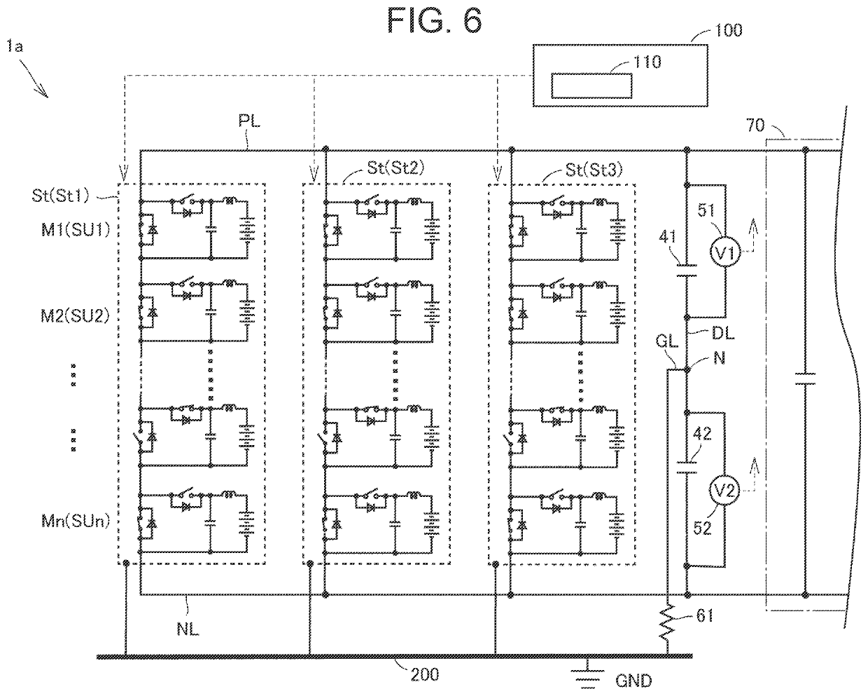

FIG. 6 is a view showing the schematic configuration of a power source system 1a in a modified example. In the modified example, a plurality of (three) battery strings St1 to St3 is connected in parallel to the positive electrode line PL and the negative electrode line NL and connected to the inverter 70. The detection line DL including the first capacitor 41 and the second capacitor 42 connected in series connects the positive electrode line PL and the negative electrode line NL to each other. The detection line DL between the first capacitor 41 and the second capacitor 42 is connected at its middle point N to the ground line GL, and is grounded by being connected to the metal shelf 200 or the like of the power source system 1 through the limiting resistor 61. The other components and the processing by the electric leakage detection unit 110 are the same as in the above-described embodiment and therefore description thereof will be omitted.

According to this modified example, by obtaining the differential voltage ΔV (=|V1−V2|) from detection signals of the first voltage sensor 51 and the second voltage sensor 52, electric leakage in a plurality of (three) battery strings St connected in parallel can be detected.

The embodiment disclosed this time should be construed as being in every respect illustrative and not restrictive. The scope of the present disclosure is indicated not by the foregoing description of the embodiment but by the claims, and is intended to include all changes within the meaning and scope of equivalents of the claims.

What is claimed is:

1. A power source system comprising a battery string in which a plurality of battery circuit modules is connected in series,
each of the plurality of battery circuit modules including:
a battery;
a first switch connected in parallel to the battery;
a second switch connected in series to the battery; and
a first output terminal and a second output terminal to which a voltage of the battery is applied when the first switch is in an OFF state while the second switch is in an ON state,
the power source system further comprising:
a control device that controls an output voltage of the battery string by controlling ON/OFF states of the first switch and the second switch;
a first capacitor and a second capacitor that are connected in series to a detection line connecting a positive electrode output line and a negative electrode output line of the battery string to each other;
a ground line that grounds the detection line between the first capacitor and the second capacitor through a limiting resistor;
a first voltage sensor that acquires a first voltage that is a voltage of the first capacitor;
a second voltage sensor that acquires a second voltage that is a voltage of the second capacitor; and
an electric leakage detection unit that detects electric leakage in the battery string, wherein:
the electric leakage detection unit is configured to execute a first electric leakage detection process and a second electric leakage detection process during operation of the battery string;
the first electric leakage detection process includes a process of determining that electric leakage exists in the battery string when a differential voltage that is a difference between the first voltage and the second voltage is equal to or higher than a predetermined value; and
the second electric leakage detection process includes a process of setting at least one battery circuit module among the plurality of battery circuit modules in a pass-through state in which the first switch is in a normally ON state while the second switch is in a normally OFF state, and determining that electric leakage exists in the battery string when the differential voltage is equal to or higher than the predetermined value.

2. The power source system according to claim 1, wherein the electric leakage detection unit executes the second electric leakage detection process when the electric leakage detection unit has determined in the first electric leakage detection process that no electric leakage exists in the battery string.

3. The power source system according to claim 1, comprising a plurality of battery strings that is connected in parallel, wherein:
each of the plurality of battery strings is formed by the battery string; and
the detection line connects to each other a positive electrode line to which a positive electrode output line of each of the plurality of battery strings is connected and a negative electrode line to which a negative electrode output line of each of the plurality of battery strings is connected.
